(19) United States
(12) Patent Application Publication
(10) Pub. No.: US 2012/0182713 A1
(43) Pub. Date: Jul. 19, 2012

(54) LIGHTING UNIT WITH LIGHT EMITTING ELEMENTS

(76) Inventor: Eric Bretschneider, Satellite Beach, FL (US)

(21) Appl. No.: 13/272,008

(22) Filed: Oct. 12, 2011

Related U.S. Application Data
(60) Provisional application No. 61/433,151, filed on Jan. 14, 2011.

(51) Int. Cl. F21V 7/04; H05K 13/00; F21V 29/00; F21K 2/00; F21V 21/00

(52) U.S. Cl. 362/84; 362/235; 362/217.01; 362/218; 29/592.1

(57) ABSTRACT

The invention provides systems and methods for providing illumination. A lighting unit may be provided with a support structure, a circuit board supporting a plurality of light emitting elements, and a base optical member. The circuit board may be flexible, and may be curved to provide strong thermal contact with the support structure. The light emitting elements may extend beyond a side of the circuit board. The base optical element may have castellations, wherein the light emitting elements may be located between the castellations.

### CROSS-REFERENCE

This application claims the benefit of U.S. Provisional Application No. 61/433,151, filed Jan. 14, 2011, which application is incorporated herein by reference.

### BACKGROUND OF THE INVENTION

Fluorescent lamps are widely used for lighting in commercial buildings, residential spaces, as well as on transit buses and in outdoor lighting. Fluorescent lighting provides some advantages, such as improved efficiency, over other lighting options such as incandescent lighting. However, there are several drawbacks. Fluorescent lamps fail under excessive vibration, require a high operating voltage, consume a large amount of power, generally have poor color quality, they cannot be started in cold temperatures or in humid environments, they emit light in 360 degrees about the length of the lamp such that much light is lost in reflection, and they contain mercury, making the lamps difficult to dispose of and hazardous to human health and the environment.

Various solutions offering light emitting diode (LED) based fluorescent tube replacement lamps have been proposed in U.S. Pat. Nos. 7,049,761, 7,114,830, and 7618157, which are hereby incorporated by reference in their entirety. U.S. Pat. No. 7,049,761 describes fluorescent tube replacement lamps having a row of white LEDs directed towards the area of desired illumination. The LEDs appear as point sources along the length of the lamp, so light is harsh, not uniform or well distributed, and limited to the color quality and consistency of the LED sources. A refracting or scattering cover can be used to diffuse the light for a more uniform appearance, but this either adds significant cost (for a highly efficient diffuser) or loss of lamp efficiency. Furthermore, LEDs generate significant amounts of heat which reduces the lifetime and efficiency of the LED devices. In these lamps, the LED devices are enclosed in a tubular bulb, further increasing the operating temperature due to the large amount of trapped heat. Some lamps incorporate a horizontal heat sink, but such a heat sink, even with fins or grooves, is not very effective. U.S. Pat. No. 7,114,830 describes a fluorescent tube replacement lamp that has LEDs directed towards the area of desired illumination as described above, or directed towards a reflector. The reflector can be used to scatter light out of the lighting unit for a more uniform distribution of the light, however there will still be bright spots. The heat management problems are not addressed. Largely due to heat management issues, these proposed fluorescent tube replacement lamps will have reduced system efficacy, reduced lumen maintenance, problems with color consistency over lifetime, and uncertain reliability. U.S. Pat. No. 7,618,157 proposes a series of blue LEDs exciting a remote phosphor positioned on a plastic cover. Though this patent provides more uniform light, it requires a large amount of phosphor material to manufacture. Phosphor material can be extremely expensive, thus preventing achieving the cost goals required for adoption of this technology. Furthermore, though thermal issues are mitigated with the use of a remote phosphor, thermal management is not optimized and may result in reduced system efficacy, lumen maintenance issues, and uncertain reliability.

Therefore, a need exists for improved systems and methods of illumination. A further need exists for a lighting unit with improved thermal management and efficiency.

### SUMMARY OF THE INVENTION

An aspect of the invention is directed to a lighting unit. The lighting unit may comprise a support structure, a circuit board extending substantially along the length of the support structure, a plurality of light emitting elements disposed along a length of the circuit board, and an at least partially reflective reflector extending substantially along the length of said support with a plurality of shaped features covering at least a portion of the circuit board edge between the light emitting elements.

In accordance with another aspect of the invention, a lighting strip may comprise a support structure, a circuit board extending substantially along the length of the support structure, and a plurality of light emitting elements disposed along a length of the circuit board and extending over an edge said circuit board.

An additional aspect of the invention may be directed to a lighting unit comprising a heat-dissipating support structure with a curved surface; a flexible circuit board extending substantially along the length of the support structure that is curved to provide contact the curved surface of the support structure; and a plurality of light emitting elements disposed along a length of the circuit board.

A method of assembling a lighting unit may be provided in accordance with another aspect of the invention. The method may comprise providing a curved heat-dissipating structure; providing a flexible circuit board with a plurality of light emitting elements; and inducing a curvature in the flexible circuit board such that the portion of the circuit board with the light emitting elements is brought into intimate contact with the curved heat-dissipating structure without directly applying force to said portion of the circuit board.

Other goals and advantages of the invention will be further appreciated and understood when considered in conjunction with the following description and accompanying drawings. While the following description may contain specific details describing particular embodiments of the invention, this should not be construed as limitations to the scope of the invention but rather as an exemplification of preferable embodiments. For each aspect of the invention, many variations are possible as suggested herein that are known to those of ordinary skill in the art. A variety of changes and modifications can be made within the scope of the invention without departing from the spirit thereof.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1 provides an exploded view of a lighting unit provided in accordance with an embodiment of the invention.

FIG. 2 provides an example of an optical element provided in accordance with an embodiment of the invention.

FIG. 3A is an example of a circuit board with overhanging light emitting elements.

FIG. 3B shows a side view of a light emitting element hanging over a circuit board.

FIG. 3C shows another side view of a light emitting element hanging over a circuit board.

FIG. 3D shows an alternate embodiment of the invention with light emitting elements hanging over a circuit board, with a substrate supporting the light emitting elements by protruding from an edge of the circuit board.

FIG. 4 illustrates an example of a flexible circuit board fitted with the optical element with light emitting elements located between castellations of the optical element.

FIG. 5A illustrates an example of a flexible circuit board contacting a heat dissipating support.

FIG. 5B illustrates another example of a flexible circuit board contacting a heat dissipating support.

FIG. 6A shows an example of an assembled lighting unit provided in accordance with an alternate embodiment of the invention.

FIG. 6B shows another example of an assembled lighting unit provided in accordance with another embodiment of the invention.

FIG. 7A shows a cross-section of an assembled lighting unit in accordance with an alternate embodiment of the invention.

FIG. 7B provides a cross-sectional view of an assembled lighting unit in accordance with another embodiment of the invention.

### DETAILED DESCRIPTION OF THE INVENTION

While preferred embodiments of the invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention.

The invention provides systems and methods for providing illumination. Various aspects of the invention described herein may be applied to any of the particular applications set forth below or for any other types of lighting units or lighting strips. The invention may be applied as a standalone system or method, or as part of an integrated illumination system. It shall be understood that different aspects of the invention can be appreciated individually, collectively, or in combination with each other.

### Lighting Unit

An aspect of the invention relates to lighting units which may be used for illumination. A lighting unit may provide light suitable for general illumination. A lighting unit may be used as a replacement lamp for conventional lighting fixtures or as a standalone light source. A lighting unit may be configured to replace a conventional fluorescent light tube in a conventional fluorescent lighting fixture. A lighting unit may be highly efficient and provides good quality light while having the potential to be manufactured at low cost.

A lighting unit may be in a circular, linear, polygonal, curved, curvilinear u-shaped, or other form. The lighting unit may be in a substantially tubular form to mimic the appearance of a conventional fluorescent light tube. The lighting unit may have a substantially linear shape. The lighting unit may be formed of one or more lighting strips. A lighting strip may have a substantially linear shape. A lighting strip may have a shape, such as a straight line, bent line, or curve.

A lighting unit may have one or more connector configured to mechanically and/or electrically couple the lighting unit to a light receptacle. In some embodiments, the connector may be an end cap. In some embodiments, the light receptacle may be a conventional fluorescent light receptacle. Coupling may be achieved, for example, through the use of conductive pins protruding from the end caps, as is used in conventional fluorescent light tube to receptacle coupling schemes. Each end cap may have one or two conductive pins, or the electrical coupling can occur at one end cap having two conductive pins, for example. In one embodiment, least one of the end caps may be used only for mechanical coupling. In some embodiments, coupling may be used by any other electrically conducting arrangement.

In some embodiments, the lighting unit may operate as a standalone light source and luminaire which may have a circular, linear, polygonal, curved, curvilinear, “x”-shape, “z”-shape, polyhedron, sphere, or other two-dimensional, or three-dimensional shape, for example. In other embodiments, the lighting unit may operate as a replacement lamp for use in other conventional luminaires.

The lighting unit may be configured to be powered by line alternating current or direct current. In some embodiments, a power converting supply may be directly integrated into the lighting unit.

The lighting unit of the present work may be used for general illumination or specialty lighting applications such as phototherapeutic applications, grow lighting, display lighting, architectural lighting, medical lighting, inspection lighting, decorative lighting, backlighting, or signage.

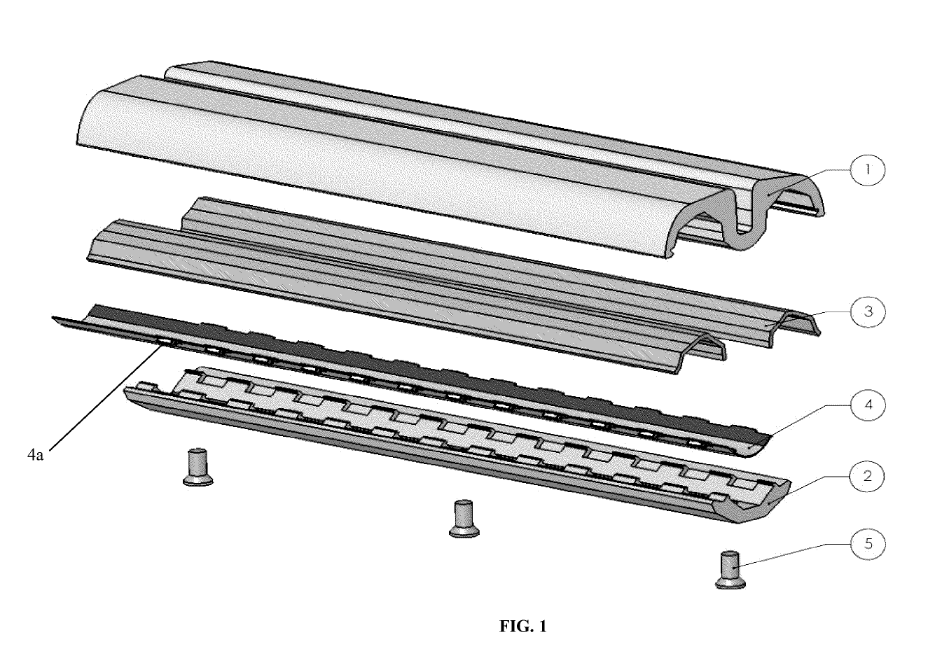

FIG. 1 provides an exploded view of a lighting unit provided in accordance with an embodiment of the invention. The lighting unit may include one or more of the following: support structure 1, first optical element 2, second optical element 3, circuit board 4 with one or more light emitting elements 4a, and fastener 5.

A lighting unit may have a primary direction of illumination. As shown in FIG. 1, for example, the direction of illumination may be downward, wherein the side of the lighting unit accepting the fastener is a downward direction. Light may be emitted in multiple directions with a primary direction of illumination downward toward one or more fastener. Alternatively, a primary direction of illumination may be toward a side or upward relative to the fastener. In some embodiments, an upper surface or top of the lighting unit may be on a side opposite the direction of illumination and a lower surface or bottom of the lighting unit may be on the side in the direction of illumination. The lighting unit may be oriented in any manner with relation to its surroundings. The direction of illumination may be in any direction relative to the surroundings of the lighting unit. For example, the direction of illumination may be toward the ground or floor. In other examples, the direction of illumination may be toward a ceiling or sky, or sideways or toward a wall, or at any angle therebetween.

In some embodiments, an optical element, such as the second optical element 3, may be in contact or fitted to the support structure 1. In some embodiments, the optical element may be complementary in shape to the support structure. For example, the support structure may have a plurality of facets extending lengthwise along the support structure, and the optical element may also include a complementary plurality of facets extending lengthwise along the optical element. The complementary plurality of facets on the optical element may allow the optical element to be fitted to the support structure. The optical element may be disposed on the surface of the support structure. In other embodiments, an optical element may be integrally formed with the support structure as a single unit. For example, the surface of the support structure may include a desired optical property as provided by the optical element.

A plurality of optical elements may contact the support structure. For example, two secondary optical elements 3 may contact the support structure. The two secondary optical elements may be on the side of the support structure in the direction of illumination. In some embodiments, the two secondary optical elements may be provided on an underside of the support structure.

In some embodiments, a circuit board 4 may also contact a support structure 1. The circuit board may or may not contact a secondary optical element 3. A circuit board may be provided downward in the direction of illumination relative to the secondary optical element. In some embodiments, a circuit board may be located between two or more secondary optical elements or beneath a region between two or more secondary optical elements.

An optical element may contact the circuit board 4. The optical element may be one or more primary optical element 2. The primary optical element may be provided downward in the direction of illumination relative to the circuit board. The primary optical element may be beneath the circuit board.

### Support Structure

A lighting unit may include a support structure which may be rigid or semi-rigid. The support structure may provide support to one or more component of the lighting unit.

The support structure may have a linear configuration, or any other configuration, including those described elsewhere herein. The support structure may have a length that is greater than any other dimension (e.g., width, height) of the support structure. In some embodiments, a space may be provided between portions of the support structure. The support structure may include a lower surface in the direction of illumination. In some embodiments, the lower surface may include one, two, or more shaped features. For example, two substantially parallel shaped features may be provided. The space may be provided between the two shaped features. In some embodiments, the cross-sectional shape of the shaped features may be concave when viewed from a lower perspective. The lower shaped surface may include one, two, three, four, five, six, seven, eight or more facets extending lengthwise along the support structure. In alternate embodiments, the lower shaped surface may be curved, may include facets with other orientations, or any combination thereof. The lower surface may be smooth, rough, or any combination thereof.

The support structure may be formed of a single integral piece. Alternatively, the support structure may be formed of multiple pieces.

A support structure may be a heat dissipating support structure. A heat dissipating support structure may function as a heat sink. For example, a heat dissipating support structure can be formed of a material of high thermal conductivity. For example, the heat dissipating support structure can be formed of one or more material with a thermal conductivity of about 10 W/mK or more, 50 W/mK or more, 100 W/mK or more, 150 W/mK or more, 200 W/mK or more, 250 W/mK or more, 300 W/mK or more, 400 W/mK or more, or 500 W/mK or more. The heat dissipating support structure can be formed of a thermally conductive metal such as aluminum, copper, gold, silver, brass, stainless steel, iron, titanium, nickel, or alloys or combinations thereof. The heat dissipating structure can be formed of any other thermally conductive material such as a thermally conductive plastic, diamond, or graphene. In some embodiments, the heat dissipating support structure can form the sides of the convection path, making a chimney for heat escape from the lighting unit. See, e.g., Patent Application Ser. No. 61/338,268 filed Feb. 17, 2010, which is hereby incorporated by reference in its entirety. The heat dissipating support structure may have thermal fins, grooves, knobs, pins, rods, or other features to further improve the cooling of the LEDs.

The support structure may be optional. In some instances, a circuit board may function as a support structure. For example, a circuit board as described further below may function as a support structure or be integrally formed as part of a support structure.

### First Optical Element

An optical element may be included as part of a lighting unit. In some embodiments, a primary optical element may be positioned proximate to or may contact a circuit board. In some embodiments, a primary optical element may be positioned beneath the circuit board. A primary optical element may be shaped extend over a side or a portion of a side of the circuit board. The primary optical element may be a base reflector.

In some embodiments, a primary optical element may extend along the length of the lighting unit. For example, the primary optical element may have substantially the same length as a support structure and may extend along the length of the support structure.

A lighting strip may have one or more primary optical elements to distribute light in a region or regions of desired illumination. In some instances, the primary optical elements distribute light indirectly to the regions of desired illumination. The primary optical elements may optionally distribute light to a secondary optical element that may further distribute light in a region or regions of desired illumination. The optical elements may have light reflecting components, light refracting components, light diffracting components, or a combination thereof. The optical element may have a diffuser, a lens, a mirror, optical coatings, dichroic coatings, grating, textured surface, photonic crystal, or a microlens array, for example.

The optical element may be any reflective, refractive, or diffractive component, or any combination of reflective, refractive, or diffractive components. For instance, the optical element may be both reflective and refractive. For example, a transparent optical element may be used, which may reflect light off of the first optical surface and refract light passing through the optical element. Reflective optical elements can be specular reflective material or diffuse reflective material. Diffuse reflective optical elements can further aid in broadening the distribution of light.

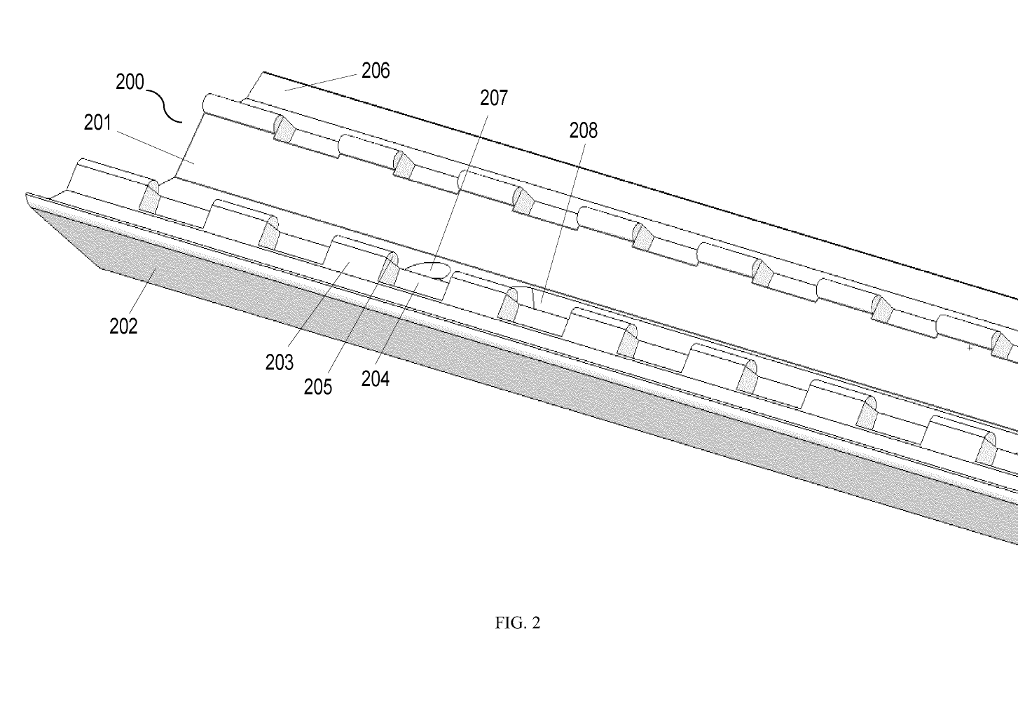

FIG. 2 provides an example of an optical element 200 provided in accordance with an embodiment of the invention. In some embodiments, the optical element may be an at least partially reflective reflector. In some embodiments, the optical element may be substantially non-transmissive of light. For example, light need not pass through the optical element. The optical element may be formed of an opaque, translucent, or transparent material. The optical element may have regions that are reflective and regions that are not reflective or only partially reflective. Portions of the optical element may transmit light. In one embodiment, the optical element may be partially reflective and partially transmissive, allowing light to transmit through and reflect from the optical element.

In some embodiments, a surface of the optical element may have a high reflectivity. For example, the surface may be greater than, less than, or equal to about 50%, 60%, 70%, 80%, 90%, 92%, 94%, 95%, 96%, 97%, 98%, or 99% reflective.

In further embodiments, all or portions of the first optical element may be at least partially translucent. Furthermore, the first optical element can be formed of a plurality of pieces, of which one, two, three or more as well as all pieces may be at least partially translucent, wherein the translucent pieces may or may not be formed of the same material. The first optical element may be formed of a mix of pieces formed from one or more translucent materials and pieces formed from other materials in accordance with the present invention. For example, the first optical element may be formed from a translucent plastic. The translucent first optical element may provide advantages as described elsewhere herein. Additionally, the translucent first optical element may provide an efficiency gain by passing light through the optical element that may otherwise be lost in an opaque optical element. In one example, involving a ceiling lighting application in accordance with the present invention, light may pass downward through the first optical element.

An optical element, such as a lower reflector or an upper reflector, may have any degree of translucency. Translucent optical elements may have both opaque and transparent characteristics, wherein the translucent material may reflect as well as transmit light. As defined herein, translucent materials used in optical elements in accordance with the present invention may have a specular and/or diffuse reflectivity and a diffuse transmissivity in any relative proportion. For example, a translucent material may reflect 50% of incident light, while transmitting 50% of the incident light and so on. In a limiting case, a material may be referred to as opaque when it ceases to transmit light. An opaque material may be reflective. A material which is not limited to diffuse light transmission may be referred to as transparent. A transparent material may be reflective as well as transmissive. Any description of optical elements herein referring to translucent materials may also be applied to transparent materials. Optical elements may be formed from pieces with substantially reflective, transparent or translucent properties.

In some embodiments, the optical element has one or more smooth surface. Alternatively, the optical element may have a rough surface, or may include one or more surface features such as facets, diffraction grating, holes, protrusions, ridges, indentations, channels, or grooves.

The optical element can be formed of a plastic or polymer material. Alternatively, the optical element can be formed of metal, glass, or any other reflective material. In some embodiments, the optical element can include a reflective metal surface. The metal surface may be disposed on a supporting member. For example, the optical element can be a reflective strip of tape disposed on a supporting member, or a metallic layer evaporated onto a supporting member. The optical element may be a polished surface of a metallic piece. The optical element may be mirrored.

The optical element may have an inner concave surface 201 and an outer convex surface 202. In some embodiments, the concave surface may be an upper surface of the optical element and the convex surface may be a downward surface of the optical element. In some embodiments, the concave and/or convex surface may be formed by a plurality of flat surfaces extending lengthwise along the optical element. In other embodiments, the concave and/or convex surface may be formed by one or more curved surface extending lengthwise along the optical element.

The optical element may include one or more castellations. Castellations may include protruding portions 203 and recessed portions 204. In some embodiments, the protruding portions and recessed portions may have straight edges or corners, while in other embodiments, the protruding portions and recessed portions may have rounded edges or corners. In some embodiments, the edges of the castellations may be substantially perpendicular to one another (e.g., have a rectangular profile). In other embodiments, the edges of the castellations may have other angles to one another (e.g., have a trapezoidal profile). In some embodiments, the protruding portions may include a lip or extension 205. The lip or extension may extend the about the thickness of a circuit board or even further. In some embodiments, the lip or extension may be rounded while in other embodiments the lip or extension may have sharp straight edges or corners. In some embodiments, the length of the protruding portion of the castellation may be greater than, less than, or substantially equal to the length of the recessed portion of the castellation.

The castellations may be provided lengthwise along the optical element. In some embodiments, one, two, or more rows of castellations may be disposed on the optical element. Rows of castellations may be substantially parallel to one another. The castellations may be located on an upper surface of the optical element. The castellations may be located on a surface of the optical element facing one or more light emitting elements. The castellations may be located adjacent to or at the ends of a concave surface of the optical element.

The castellations may be oriented at an angle. In some embodiments, the castellations may be angled sideways, upwards, or at any angle in between (e.g., about 15 degrees, 30 degrees, 45 degrees, 60 degrees, or 75 degrees). The castellations may be oriented at an angle to reflect light emitted from a light emitting element upward to a secondary optical element.

The optical element may have one or more ridge 206. The ridge may be extended upward and sideways. The ridge may assist with reflecting light emitted from one or more light emitter. The ridge may prevent light emitted from a light emitter from directly leaving the lighting unit.

A first optical element may have one or more hole 207 or passageway 208. For example, an optical element may have one, two, three, four, or more holes configured to allow a fastener to pass through. One, two, three, four, or more passages may be provided. A passageway of the optical element may permit the flow of air or other fluid through the lighting unit. In some embodiments, the passageway may have an elongated shape. The passageway may optionally have a cross-sectional area greater than, or equal to about 3%, 5%, 7%, 10%, 12%, 15%, 20%, 25%, 30%, or 50% of the optical element. The passageway may have a width greater than, or equal to about 0.5 mm, 1 mm, 1.5 mm, 2 mm, 2.5 mm, 3 mm, 4 mm, 5 mm, 6 mm, 7 mm 8 mm, 9 mm, 10 mm, 12 mm, 15 mm, or 20 mm. In some instances, the width:length ratio of the passageway may be about 1:20, 1:15, 1:10, 1:7, 1:5, 1:4, 1:3, 1:2, or 1:1. The passageway may advantageously permit the formation of a convection path that may cool the lighting unit. In some embodiments, the position of a hole and passageway may alternate when traveling lengthwise along the optical element. In some implementations, an optical element may have N holes and N−1 passageways, where N is a positive whole number.

The first optical element may be formed of a single integral piece. For example, the optical element can be formed of a single reflective material. Alternatively, the first optical element may be formed of a plurality of pieces. A plurality of pieces may be removably or permanently connected.

A luminescent material may be disposed on the optical element or a portion of the optical element. Alternatively, the optical element is not covered with a luminescent material.

### Second Optical Element

A second optical element may optionally be included as part of a lighting unit. In some embodiments, a secondary optical element may be positioned at some distance from a circuit board. A lighting unit may have a secondary optical unit without requiring a primary optical element as previously described. A lighting unit may have a primary optical element without requiring a secondary optical element. The secondary optical unit may be located contacting the underside of a support structure. In some embodiments, a secondary optical element may be positioned upwards of the circuit board. A secondary optical element may or may not contact the circuit board. A secondary optical element may optionally extend further to the sides of a lighting unit relative to a primary optical element or circuit board. A secondary optical element may be a top reflector.

In some embodiments, one, two, three, four or more secondary optical units may be provided for a lighting unit. A secondary optical element may extend along the length of the lighting unit. For example, a secondary optical element may have substantially the same length as a support structure and may extend along the length of the support structure. In some instances, two secondary optical elements may extend along a support structure and be substantially parallel to one another.

A lighting strip may have one or more secondary optical elements to distribute light in a region or regions of desired illumination. A secondary optical element may receive light that has been emitted from a light emitting element directly or that has been reflected or re-emitted from a primary optical element. The secondary optical elements may optionally distribute light to a primary optical element that may further distribute light back to the secondary optical element, or may distribute light to a region or regions of desired illumination. The secondary optical elements may have light reflecting components, light refracting components, light diffracting components, or a combination thereof. The optical element may have a diffuser, a lens, a mirror, optical coatings, dichroic coatings, grating, textured surface, photonic crystal, or a microlens array, for example.

The second optical element may have on one or more features as previously described for the first optical element. Any description herein of the first optical element may also apply to the second optical element, and vice versa. Furthermore, any description herein of the first optical element may apply to the first optical element exclusively, the second optical element exclusively or both the first and second optical elements, and vice versa. For example, the second optical element may or may not be fully or partially reflective. In another example, the second optical element may or may not permit the transmission of light through the second optical element. In yet another example, the second optical element may comprise cutouts or holes to allow light transmission through the optical element. In a further example, one or more at least partially translucent materials may be used to form the second optical element. The one or more translucent materials may be used to form the entirety of the second optical element or it may be used to form one or more pieces of the second optical element in combination with other materials suitable for forming an optical element in accordance with the present invention. For instance, the second optical element may be formed from a translucent plastic. The translucent second optical element may provide advantages as described elsewhere herein. For example, in a ceiling fluorescent tube replacement application in accordance with the present invention, light may shine up through the second optical element as well as down. A lighting unit thus configured may closer resemble the light distribution provided by some fluorescent tubes and may eliminate the “black hole” look of LED replacement lamps available in the art in any fixture.

A lighting unit may have any combination of optical elements with varying optical properties. For example, a lighting unit may have an opaque upper reflector and an opaque lower reflector, an opaque upper reflector and a translucent lower reflector, a translucent upper reflector and an opaque lower reflector, or a translucent upper reflector and a translucent lower reflector. Any description of a translucent reflector may also apply to a transparent reflector. A lighting unit may have any combination of opaque, translucent, and/or transparent upper reflector, with any combination of opaque, translucent, and/or transparent lower reflector. For example, a lighting unit may have an upper reflector formed from pieces with opaque and translucent properties and a lower reflector formed from pieces with opaque and transparent properties, an upper reflector formed from one or more translucent pieces and a lower reflector formed from pieces with opaque and transparent properties, and so on.

The optical element may be any reflective, refractive, or diffractive component, or any combination of reflective, refractive, or diffractive components. For instance, the optical element may be both reflective and refractive. For example, a transparent optical element may be used, which may reflect light off of the first optical surface and refract light passing through the optical element. Reflective optical elements can be specular reflective material or diffuse reflective material. Diffuse reflective optical elements can further aid in broadening the distribution of light.

FIG. 1 shows a plurality of secondary optical elements 3 provided in accordance with an embodiment of the invention. In some embodiments, the optical element may be an at least partially reflective reflector. In some embodiments, the optical element may be substantially non-transmissive of light. For example, light need not pass through the optical element. The optical element may be formed of an opaque, translucent, or transparent material. The optical element may have regions that are reflective and regions that are not reflective or only partially reflective. Portions of the optical element may transmit light. In one embodiment, the optical element may be partially reflective and partially transmissive, allowing light to transmit through and reflect from the optical element.

In some embodiments, a surface of the optical element may have a high reflectivity. For example, the surface may be greater than, less than, or equal to about 50%, 60%, 70%, 80%, 90%, 92%, 94%, 95%, 96%, 97%, 98%, or 99% reflective. In some embodiments, a secondary optical element may be more reflective than, less than reflective than, or about equally reflective to a primary optical element.

In some embodiments, the optical element has one or more smooth surface. Alternatively, the optical element may have a rough surface, or may include one or more surface features such as facets, diffraction grating, holes, protrusions, ridges, indentations, channels, or grooves.

The optical element can be formed of a plastic or polymer material. Alternatively, the optical element can be formed of metal, glass, or any other reflective material. In some embodiments, the optical element can include a reflective metal surface. The metal surface may be disposed on a supporting member. For example, the optical element can be a reflective strip of tape disposed on a supporting member, or a metallic layer evaporated onto a supporting member. The optical element may be a polished surface of a metallic piece. The optical element may be mirrored. The optical element may optionally have a luminescent material disposed thereon. The optical element may have a luminescent material as provided by WhiteOptics LLC.

The optical element may have an inner concave surface and an outer convex surface. In some embodiments, the convex surface may be an upper surface of the optical element and the concave surface may be a downward surface of the optical element. Thus, the concave portion of the optical element may be directed downward. In some embodiments, the concave and/or convex surface may be formed by a plurality of flat surfaces extending lengthwise along the optical element. The secondary optical element may be formed of a plurality of facets that extend lengthwise along the optical element. In some embodiments, about 1, 2, 3, 4, 5, 6, 7, 8 or more facets may be provided. In other embodiments, the secondary optical element surface may be formed by one or more curved surface extending lengthwise along the optical element.

The secondary optical element may be formed of a thin piece. In some embodiments, the secondary optical element may be fitted into a support structure so that the upper surface of the secondary optical element contacts the support structure and the lower surface of the secondary optical element is exposed and directed downward. In some embodiments, an exposed side of the secondary optical element opposite the side covered by the support structure may have luminescent material disposed thereon. Alternatively, the secondary optical element does not have luminescent material. In some embodiments, an exposed surface of the secondary optical element is a concave side of the optical element.

The secondary optical element may be attached to the support structure by using an adhesive, thermal grease, or any other material. In some embodiments, the secondary optical element can be snap fitted, pressure fitted, locked, mechanically fastened, tied or otherwise permanently or removably affixed to the support structure. In one example, the secondary optical element can have a lip that may fit into a groove within the support structure, allowing the secondary optical element to snap fit into the support structure.

A second optical element may be formed of a single integral piece. For example, the optical element can be formed of a single reflective material. Alternatively, a second optical element may be formed of a plurality of pieces. A plurality of pieces may be removably or permanently connected. Alternatively, in some embodiments, a separate second optical element need not be provided, and the functions or features of the secondary optical element may be integral to the support structure. For example, the underside of the support structure may have a reflective surface and may include a plurality of facets or be curved as described.

The shape of the secondary optical element can define the distribution of light from the lighting unit. Additionally, the curvature, facets, or mounting angle of the secondary optical element with respect to the position of the primary optical element and light emitting elements can define the distribution of light from the lighting unit. The facets or curvature of the optical element can be configured to provide a broad distribution of light. In some implementations, rather than a continuous reflective coating, the optical element can comprise reflective regions on the interior surface of the optical element. Furthermore, the optical element can be an extension of the support structure, for example. The reflective regions can be made, for example, by polishing the interior surface of the support structure or by deposition of a thin reflective film on a support structure surface. Additionally, the shape or configuration of the secondary optical element can be changed to achieve a different distribution of light. For example, the radius of curvature of the optical element may be reduced in order to achieve a narrower distribution of light. Light directed towards the optical element may experience multiple reflections off of the optical element before being directed towards another optical element or exiting the lighting unit.

Refractive optical elements can be diffusers to aid in providing a more uniform light distribution.

In some embodiments, the lighting unit may comprise one or more secondary optical elements that are positioned before the primary optical element, such that a portion of the light emitted from the light emitting elements is incident on the at least one secondary optical element. The at least one secondary optical element may direct light to the primary optical element, to another optical element, or out of the device.

Using optical elements, luminescent materials, or a combination thereof, a very broad distribution of light can be achieved from even point source light emitting elements. Thus, a highly efficient, diffuse light source can be obtained. A luminescent material can also further range in color quality and color consistency of the light provided by the lighting unit. A luminescent material may be disposed on the optical element or a portion of the secondary optical element. Alternatively, the secondary optical element is not covered with a luminescent material.

Luminescent Material

A luminescent material may be disposed on an optical element. In some embodiments, a luminescent material may be disposed on a primary optical element or a secondary optical element. A luminescent material may be disposed on a portion or all of a first optical element proximate to a plurality of light emitting elements or a luminescent material may be disposed on a portion or all of a second optical element further away from the plurality of light emitting elements. A luminescent optical element may be disposed on both a primary optical element and second optical element, may be disposed on a primary optical element without being disposed on a second optical element, may be disposed on a secondary optical element without being disposed on a primary optical element, or may be disposed on neither a primary nor secondary optical element. A luminescent material may be disposed on no optical elements, one optical element, some optical elements, or all optical elements provided in a lighting unit. A luminescent material may be disposed on part of the exposed optical element surface or over the entire exposed optical element surface. One or more of the optical elements (e.g., primary or secondary optical element) may be a reflector.

In some implementations, a luminescent material may be disposed on a support structure. The luminescent material may alternatively not be disposed on a support structure. The luminescent material may cover a portion or all of the support structure.

The light emitting elements and optical element (e.g., base reflector) may be positioned such that light emitted from the light emitting elements may be at least partially directed towards the luminescent material.

A luminescent material can be any material or combination of materials that phosphoresces or fluoresces when excited by light from the light emitting elements. The luminescent material can be an inorganic material, an organic material, or a combination of inorganic and organic materials. The luminescent material can be a quantum-dot based material or nanocrystal. Numerous luminescent material formulations can be used dependent on the excitation spectra provided by the light emitting elements and the output light characteristics desired. For example, when the light emitting elements provide an emission spectrum yielding white light with a high correlated color temperature, phosphors emitting light of a red and/or orange wavelength can be used to achieve lower/warmer correlated color temperature white light and to improve the color rendering index. Developments in luminescent materials and applications are generally described in Adrian Kitai, Luminescent Materials and Applications, Wiley (May 27, 2008) and Shigeo Shionoya, William Yen, and Hajime Yamamoto, Phosphor Handbook, CRC Press 2^{nd} edition (Dec. 1, 2006), which are hereby incorporated by reference in their entirety.

A remote luminescent material refers to a luminescent material that is not inside or in physical contact with the light emitting element (e.g., LED package). For example, a remote luminescent material does not include any material that may be on a surface of the light emitting element.

One advantage of using a remote luminescent material is that color consistency of a lighting unit product can be enhanced through control of the formulation and deposition of the luminescent material. For instance, when LEDs are fabricated they are binned according to their color characteristics. LEDs from different bins can be used in production of lighting units without sacrificing product to product color consistency if the quantity and formulation of the luminescent material is adjusted depending upon the exact spectral power density provided by LEDs.

Another advantage of using a remote luminescent material is that there is reduced thermal quenching of the luminescent material because it is physically displaced from the heat generating LED package. Thus, the color of the light is more consistent with lifetime and operating temperature. In comparison, in a luminaire that employs a typical warm white LED, the red and/or orange phosphor material is in direct contact with the LED package and may quench rapidly as the LED is operated at higher temperature resulting in a noticeable shift in color point.

A further advantage of using a remote luminescent material is that to achieve a warmer color temperature, the selection of the luminescent material is not limited only to materials that can operate well at higher temperatures. This can open up a range of materials that are not available to typical LED configurations.

Still another advantage of using a remote luminescent material is an increased luminescent material lifetime due to the decreased operating temperature.

A luminescent material can be disposed on an optical element in various ways, including evaporation, spray deposition, sputtering, titration, baking, painting, printing, or other methods known in the art for example. In some embodiments, the optical element may comprise grooves, pockets, or knobs into or onto which the luminescent material may be disposed to control the optical distribution of the light emitted by the luminescent material.

### Circuit Board

A lighting unit may include one or more circuit board. The circuit board may be a printed circuit board (PCB). Any circuit board material known in the art may be used. One, two or more light emitting element may be provided on the circuit board. Preferably, a plurality of light emitting elements are supported by the circuit board.

The circuit board may have any shape. For example, a circuit board may be shaped as a rectangle, square, triangle, circle, ellipse, pentagon, hexagon, octagon, curved strip, bent strip, or straight strip. In some embodiments, the circuit board may have a length that is substantially longer than any other dimension of the circuit board (e.g., width, height). In some embodiments, the circuit board may have one or more side. In some embodiments, the circuit board may have a straight side. In other embodiments, a side of a circuit board may be curved or may include protrusions or indentations.

A circuit board may have one or more hole or passageway. For example, a circuit board may have one, two, three, four, or more holes configured to allow a fastener to pass through. One, two, three, four, or more passages may be provided. A passageway of the circuit board may permit the flow of air or other fluid through the lighting unit. The passageway may advantageously permit the formation of a convection path that may cool the lighting unit. In some embodiments, the position of a hole and passageway may alternate when traveling lengthwise along the circuit board. In some implementations, a circuit board may have N holes and N−1 passageways, where N is a positive whole number.

Light Emitting Elements

A circuit board may support one, two, or more light emitting elements. In some embodiments, a circuit board may have electrical connections that may provide electrical connections between light emitting elements and a power source or between light emitting elements.

Each lighting unit may have a plurality of light emitting elements. The light emitting elements may be any illumination source known in the art. For example, the light emitting elements may include a light emitting diode (LED). A light emitting element may include an LED package. A light emitting element can be formed of a semiconductor material with a primary optic. In another example, the light emitting elements may be cold cathode fluorescent lamps (CCFLs) or electroluminescent devices (EL devices). Cold cathode fluorescent lamps may be of the type used for backlighting liquid crystal displays and are described generally in Henry A. Miller, Cold Cathode Fluorescent Lighting, Chemical Publishing Co. (1949) and Shunsuke Kobayashi, LCD Backlights (Wiley Series in Display Technology), Wiley (Jun. 15, 2009). EL devices may include high field EL devices, conventional inorganic semiconductor diode devices such as LEDs, or laser diodes, as well as OLEDs (with or without a dopant in the active layer). A dopant may refer to a dopant atom (generally a metal) as well as metal complexes and metal-organic compounds as an impurity within the active layer of an EL device. Some of the organic-based EL device layers may not contain dopant. The term EL device excludes incandescent lamps, fluorescent lamps, and electric arcs. EL devices can be categorized as high field EL devices or diode devices and can further be categorized as area emitting EL devices and point source EL devices. Area emitting EL devices may include high field EL devices and area emitting OLEDs. Point source devices may include inorganic LEDs and edge- or side-emitting OLED or LED devices. High field EL devices and applications are generally described in Yoshimasa Ono, Electroluminescent Displays, World Scientific Publishing Company (June 1995), D. R. Vij, Handbook of Electroluminescent Materials, Taylor & Francis (February 2004), and Seizo Miyata, Organic Electroluminescent Materials and Devices, CRC (July 1997). LED devices and applications are generally described in E. Fred Schubert, Light Emitting Diodes, Cambridge University Press (Jun. 9, 2003). OLED devices and applications are generally described in Kraft et al., Angew. Chem. Int. Ed., 1998, 37, 402-428, and Z., Li and H. Meng, Organic Light-Emitting Materials and Devices (Optical Science and Engineering Series), CRC Taylor & Francis (Sep. 12, 2006).

The light emitting elements can produce light in the visible range (360 to 830 nm), the ultraviolet range (UVA: 315 to 400 nm; UVB: 280 to 315 nm), and/or near infrared light (700 to 1000 nm). Visible light corresponds to a wavelength range of approximately 360 to 830 nanometers (nm) and is usually described as a color range of violet through red. The human eye is not capable of seeing radiation with wavelengths substantially outside this visible spectrum such as in the ultraviolet or infrared range, but these wavelengths may be useful for applications other than lighting, such as phototherapy or inspection applications. Furthermore, ultraviolet light may be down converted by a luminescent material in the lighting strip. The visible spectrum from shortest to longest wavelength is generally described as violet (approximately 400 to 450 nm), blue (approximately 450 to 490 nm), green (approximately 490 to 560 nm), yellow (approximately 560 to 590 nm), orange (approximately 590 to 620 nm), and red (approximately 620 to 830 nm). White light is a mixture of colors of the visible spectrum that yields a human perception of substantially white light. The light emitting elements can produce a colored light or a visually substantially white light. Various light emitting elements can emit light of a plurality of wavelengths and their emission peaks can be very broad or narrow. Light emitting elements may be white LEDs or blue LEDs for example. Furthermore, in a single lighting unit, light emitting elements may comprise a combination of colors such as red and white LEDs or red, green and blue LEDs.

The light emitting elements may be mounted on at least one circuit board or may be mounted directly on a support structure and may be electrically connected to one another. For instance, light emitting elements may be connected to one another in series, in parallel, or in any combination thereof. The light emitting elements are configured to be powered by a power supply. The power supply may be an external power supply. Alternatively, the power supply may be incorporated within the lighting unit. The power supply may provide a drive condition which is a drive voltage or current appropriate to power at least some of the light emitting elements. The drive conditions can vary with time and can be programmed to change in response to feedback from a sensor or user input.

The light emitting elements may be located along one or more edge of the circuit board. The light emitting elements may be located on a lower surface of the circuit board or an upper surface of the circuit board. The light emitting elements may be located on a side of the circuit board facing a primary optical element or may be located on a side of the circuit board facing the support structure.

The light emitting elements may have a linear arrangement on a circuit board. In one example, a first axial arrangement of light emitting elements may be provided along one edge of the circuit board, and a second axial arrangement of light emitting elements may be provided along a second opposing edge of the circuit board. The first and second axial arrangements may be substantially parallel to one another. The light emitting elements may be at or near an edge of the circuit board, or may extend past an edge of the circuit board. The light emitting elements may be at or near an edge of the circuit board, or may extend past an edge of the circuit board, for any shape of the circuit board.

Overhanging Light Emitting Elements

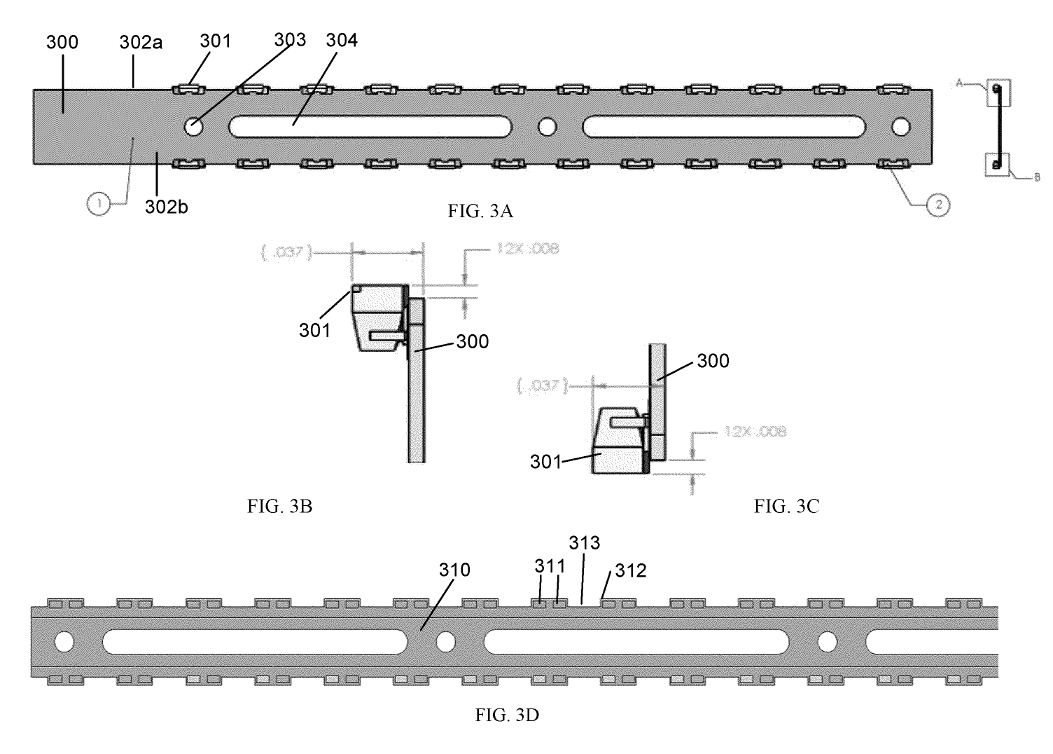

FIG. 3A is an example of a circuit board 300 with overhanging light emitting elements 301. A circuit board may be formed as a rectangular strip with a first edge 302a extending lengthwise along the circuit board and a second opposing edge 302b extending lengthwise along the circuit board. The first and second edges may be substantially parallel to one another. One, two, or more light emitting elements may be positioned hanging over the first edge. One, two, or more light emitting elements may be positioned hanging over the second edge.

In some embodiments, the light emitting elements are positioned symmetrically about an axis extending lengthwise along the circuit board through the center of the circuit board. When traveling along the length of the circuit board, a light emitting element may be positioned on a first edge and second edge along the same length of the circuit board. Alternatively, the light emitting elements may have a staggered configuration so when traveling along the length of the circuit board, a light emitting element may be positioned on a first edge without being positioned along a second edge and vice versa along the circuit board (e.g., alternating positions between first and second edge). In some embodiments, the light emitting elements may be substantially evenly spaced along the first edge. The light emitting elements may be substantially evenly spaced along the second edge. In some instances, the light emitting elements may be randomly positioned on the first and second edges. The light emitting elements may be positioned along the entire length of the circuit board, or may be positioned along portions of the length of the circuit board.

The overhanging light emitting elements may be spaced along an edge of the circuit board so that some edge of the circuit board is provided between the overhanging light emitting elements. The overhanging light emitting elements can be spaced apart so that the edge between the light emitting elements has a greater length than the light emitting elements, lesser length than the light emitting elements, or about the same length as the light emitting elements.

The circuit board may have one or more hole 303 or passageway 304. For example, a circuit board may have one, two, three, four, or more holes configured to allow a fastener to pass through. One, two, three, four, or more passages may be provided. A passageway of the circuit board may permit the flow of air or other fluid through the lighting unit. The passageway may advantageously permit the formation of a convection path that may cool the lighting unit.

FIG. 3B shows a side view of a light emitting element 301 hanging over a circuit board 300. FIG. 3C shows another side view of a light emitting element 301 hanging over a circuit board 300. Dimensions are provided by way of example only. In some embodiments, the overhanging light emitting element can be an LED package, or any other light emitting element described herein.

An overhanging light emitting element may be attached to the circuit board and may protrude over an edge of the circuit board. The overhanging light emitting element may be attached by any method known in the art including, but not limited to, soldering (e.g., eutectic soldering), brazing, adhesive, mechanical fastener, or clamp.

The light emitting element may overhang so that any amount of the light emitting element is protruding beyond the edge of the circuit board. For example, more than, less than, or equal to about 5%, 10%, 15%, 20%, 25%, 30%, 35%, 40%, 50%, 60%, 70%, or 80% of the light emitting element may hang over the edge of the circuit board. In some embodiments, the light emitting element may hang over the edge of the circuit board by more than, less than, or equal to about 0.1 mm, 0.25 mm, 0.5 mm, 0.75 mm, 1 mm, 1.5 mm, 2 mm, 3 mm, or 5 mm.

The light emitting element may emit a light in multiple directions. An overhanging light emitting element may emit light in multiple directions with portions of the light not being blocked by the circuit board. An overhanging light emitting element may simultaneously emit light in an upward and downward direction. Light from a light emitting element may simultaneously directly reach a support structure or secondary optical element and primary optical element.

An additional support may be provided in some embodiments of the invention. For example, a thin substrate may hang over the edge of the circuit board between the light emitting element and the circuit board. In some embodiment, the additional support may extend as far as the light emitting element. Alternatively, the additional support may extend less than or more than the light emitting element. In some embodiments, the additional support may provide an electrical or thermal connection between the light emitting element and the circuit board. An overhanging light emitting element may be in electrical communication with a power source and/or other light emitting elements.

FIG. 3D shows an alternate embodiment of the invention with light emitting elements 311 hanging over a side of the circuit board 310, with a portion of the circuit supporting the light emitting elements by protruding from the side of the circuit board. In some embodiments, the circuit board may have one or more edge with castellations with the protruding portion 312 of the castellations supporting one or more light emitting element and the recessed portion 313 of the castellation defining a side of the circuit board.

In some embodiments, each protruding portion of the circuit board (e.g., a protruding castellation of the circuit board), may support one light emitting element. Alternatively, each protruding portion of the circuit board may support two, three, four, or more light emitting elements. The light emitting elements may hang over the protruding portion of the circuit board. Alternatively, the light emitting elements are at or near the edge of the protruding portion of the circuit board. In some instances, the light emitting elements are supported only by the protruding portion of the circuit board. Alternatively, the light emitting elements may extend far back enough to be supported by the circuit board that is further recessed than the recessed edge of the circuit board.

The protruding portions of the circuit board may be positioned symmetrically about an axis extending lengthwise along the circuit board through the center of the circuit board. When traveling along the length of the circuit board, a circuit board protrusion may be positioned on a first edge and second edge along the same length of the circuit board. Alternatively, the protrusions may have a staggered configuration so when traveling along the length of the circuit board, a protrusion may be positioned on a first edge without being positioned along a second edge and vice versa along the circuit board (e.g., alternating positions between first and second edge). In some embodiments, the protrusions may be substantially evenly spaced along the first edge. The light emitting elements may be substantially evenly spaced along the second edge. In some instances, the protrusions may be randomly positioned on the first and second edges.

The protruding portions may be spaced along an edge of the circuit board so that some recessed edge of the circuit board is provided between the circuit board protrusions. The protruding portions can be spaced apart so that the recessed edge of the circuit board between the protrusions has a greater length than the protruding portions, lesser length than the protruding portions, or about the same length as the protruding portions.

The protruding portions may extend beyond the recessed side of the circuit board by any amount. For example, the protruding portions (such as castellations) may extend more than, less than, or equal to about 1%, 3%, 5%, 7%, 10%, 12%, 15%, 20%, 25%, 30%, or 40% width of the circuit board defined by the recessed sides of the circuit board. In some embodiments, the protruding portions may extend by more than, less than, or equal to about 0.1 mm, 0.25 mm, 0.5 mm, 0.75 mm, 1 mm, 1.5 mm, 2 mm, 3 mm, or 5 mm.

Flexible Circuit Board

The circuit board may be flexible. In some embodiments, the natural state of the circuit board may be to lie flat. In other embodiments, the natural state of the circuit board may be curved. A flexible circuit board may alter its shape when a force is exerted on the circuit board. The flexible circuit board may or may not return to its natural shape when a force is no longer exerted on the circuit board. In some embodiments, the circuit board may be flexed so that the circuit board is curved. In some embodiment, the circuit board may be curved about an axis extending lengthwise along the board. The circuit board may curve upwards so that the concave side of the circuit board is facing upwards. Alternatively, the circuit board may curve downward so that the concave side of the circuit board is facing downward. The circuit board may be curved so that the concave side of the circuit board is facing opposite the direction of illumination. The circuit board may be curved so that the concave side of the circuit board is facing in the direction of illumination.

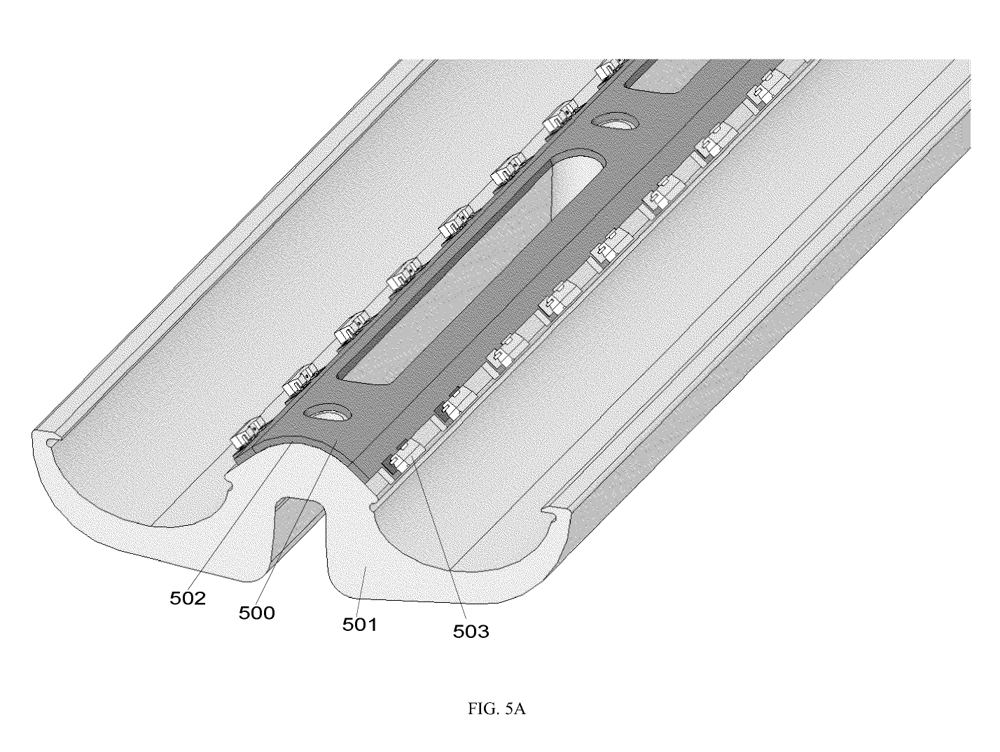

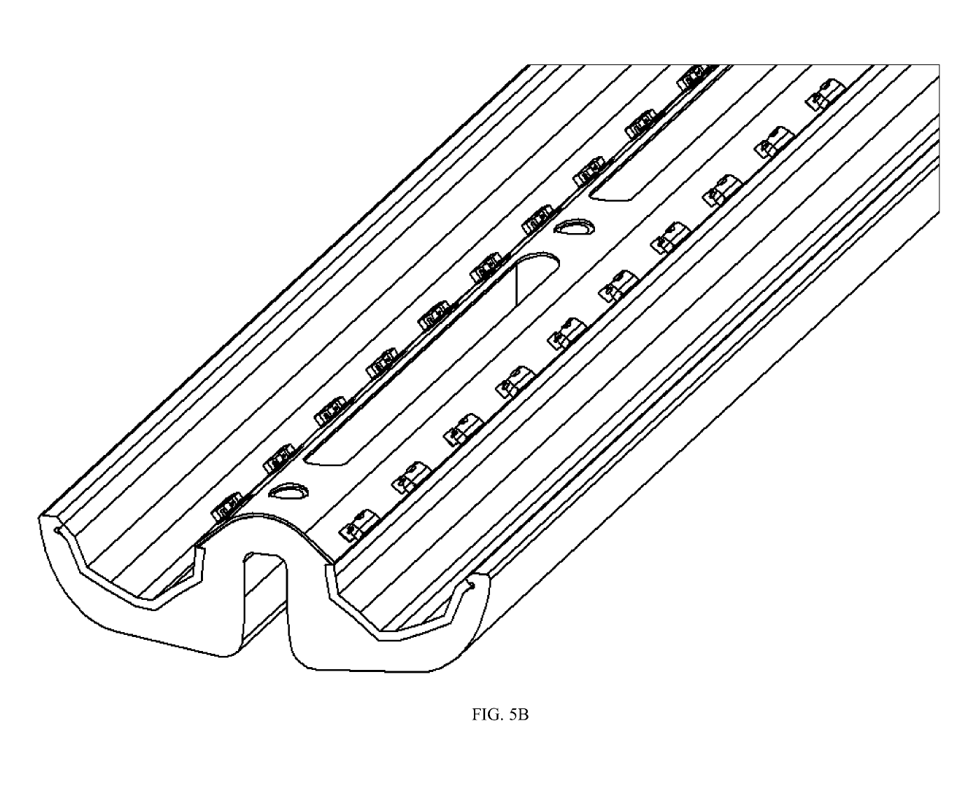

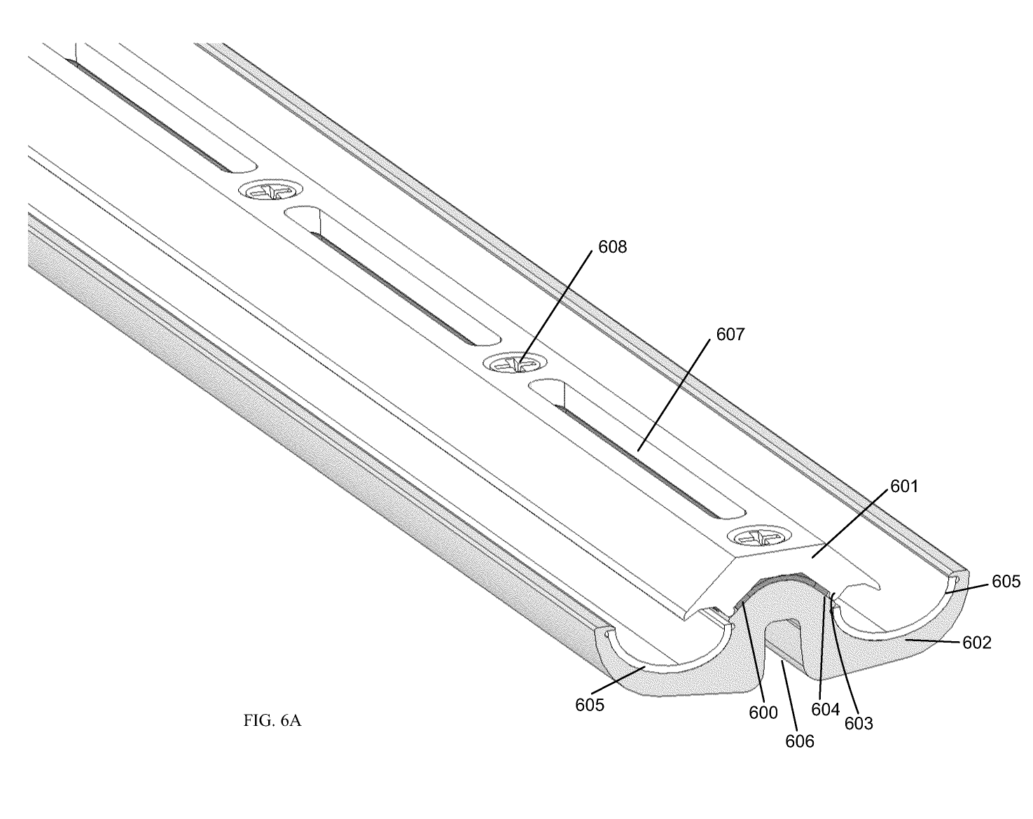

FIG. 5A illustrates an example of a flexible circuit board 500 contacting a heat dissipating support 501. In some embodiments, a support structure, such as a heat dissipating support structure, may have a convex surface 502. In some embodiments, the circuit board may be curved so that a concave side of the circuit board is directed to the support structure. In some embodiments, the circuit board may contact the heat dissipating support structure so that a curved surface of the flexible circuit board may contact a curved surface of the support structure. A flexible circuit board may extend substantially along the length of the support structure may be curved to provide contact the curved surface of the support structure. In some embodiments, the flexibility of the circuit board may allow the circuit board to make a good thermal contact with the support structure. For example, when the circuit board and support structure are pressed together, the flexibility of the circuit board may allow the circuit board shape to alter slightly to accommodate the support structure. For example, even if the cross-sectional boundaries of a support structure and circuit board are not perfectly complementary, when a convex portion of a support structure is inserted into a concave portion of the circuit board and pressed together, the circuit board shape may yield, thereby providing strong thermal contact. The circuit board may be partially wrapped about a convex portion of the support structure.

In some embodiments, when the support structure and circuit board are pressed together, a convex portion of the support structure may exert a force at or near a central axis of the circuit board extending lengthwise along the circuit board. This may increase the curvature of the flexible circuit board. This may also cause the edges of the circuit board to come closer to one another, and thereby having a stronger connection with the support structure. The edges of the circuit board may support one or more light emitting elements, which may be brought into stronger thermal communication with the support structure.

In some embodiments, heat may be generated by one or more light emitting element 503. The light emitting element may be in thermal communication with the flexible circuit board and/or the support structure. The support structure may function as a heat sink and allow heat to be transferred from the light emitting element.

FIG. 5B shows another example of a flexible circuit board contacting a heat dissipating support. As previously discussed, the heat dissipating support and/or an optical element disposed thereon may be formed of a plurality of flat facets. Optionally the facets may extend lengthwise along the length of the support. Any depiction herein of a curved support and optical element may also apply to a flat faceted surface and vice versa.

Fitting with Castellations

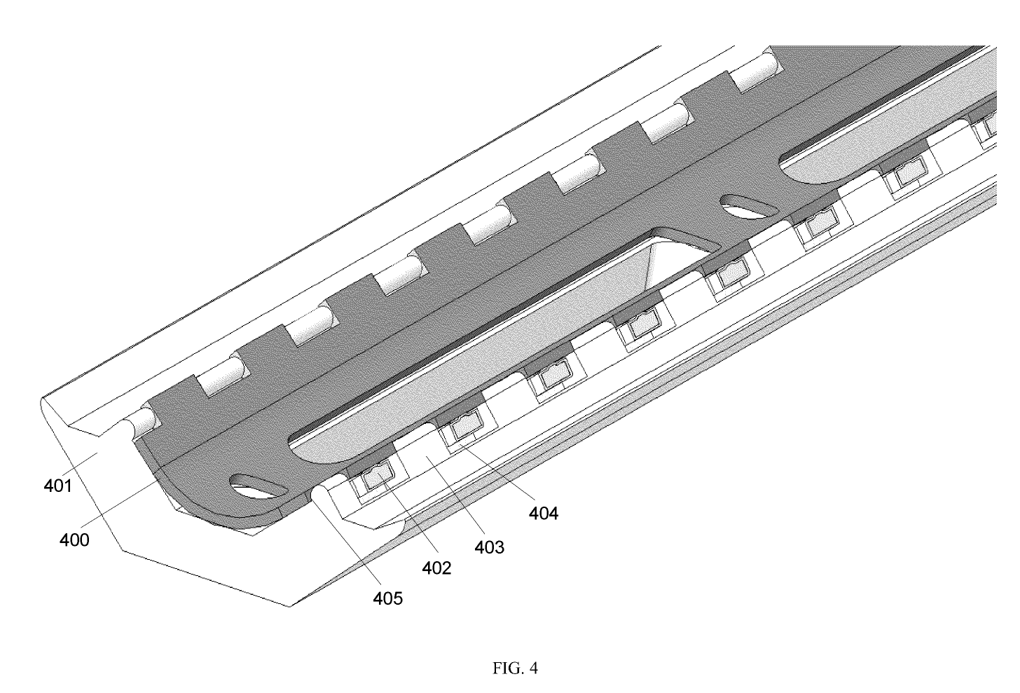

FIG. 4 illustrates an example of a flexible circuit board 400 fitted with the optical element 401 with light emitting elements 402 located between protruding portions 403 of the castellations of the optical element. In some instances, a flexible circuit board may be curved to fit within the optical element. In alternate embodiments, the flexible circuit board need not be curved and may lie flat within the optical element with castellations. In additional alternate embodiments, the circuit board need not be flexible and may have a fixed curved or flat shape that may fit with the optical element.

A circuit board may have one or more light emitting elements that may be located between protruding portions castellations of the optical element when the circuit board is fitted to the optical element. The light emitting elements may hang over a side of the circuit board. The overhanging light emitting elements may hang over an edge of the circuit board or may be supported by protruding portions of the circuit board that extend beyond a recessed edge of the circuit board.

A light emitting element may be positioned between the castellations of an optical element so that the light emitting element does not contact the optical element. For example, in some instances the light emitting element only contacts the circuit board. Alternatively, the light emitting elements may contact the optical element at some point. The lighting element may be located within recessed regions 404 of the castellations. A space may be provided around the light emitting element so that the light emitted from the light emitting element reaches the recessed portion of a castellation of the optical element. In some embodiments, at least a portion of the light may be reflected or re-emitted by the optical element. If the light emitting element is overhanging an edge of the circuit board, the light may be emitted by the light emitting element away from the castellations of the optical element.

A circuit board may have a thickness. A side face 405 may include a surface of the circuit board that has the circuit board thickness for a dimension. A first side face of the circuit board may extend lengthwise along the circuit board and its dimensions may be defined by the thickness and length of the circuit board. A second opposing side face of the circuit board may extend lengthwise along the circuit board and its dimensions may be defined by the thickness and length of the circuit board.

Castellations of the optical element may be configured to cover portions of a side face of the circuit board. For example, castellations may cover portions of a side face of the circuit board between light emitting elements. If the circuit board includes protruding portions of circuit board, the castellations may cover portions of a side face of the circuit board between the protruding portions. In some embodiments, castellations may cover about 10%, 20%, 30%, 40%, 50%, 60%, 70%, or 80% of the side face of the circuit board. The castellations may cover all or a portion of the side face between the light emitting elements or the protruding portions.

Covering a portion of a side face of a circuit board with a portion of an optical element (e.g., a castellation) may advantageously increase the relative reflective surface of the lighting unit. For example, if a side face of a circuit board is not very reflective, adding a castellation of the optical element may provide additional opportunities to reflect light.

### Fastener

A lighting unit may include any number (e.g., one, two, three, four or more) fasteners. A fastener may be used to connect one or more components of a lighting unit. For example, a fastener may cause a support structure, circuit board, and primary optical element to contact one another. In some embodiments, a fastener may be used to tighten one or more components of a lighting unit together. For example, one or more fastener may cause a strong contact between the support structure, circuit board, and primary optical element. In some embodiments, a strong contact may assist with heat dissipating from one or more light emitter disposed on the circuit board.

The fasteners may have any configuration or arrangement that may allow them to connect the primary optical element, support structure, and circuit board. For example, the fasteners may be provided in a linear axial arrangement.

The fastener may pass through a circuit board and/or primary optical element. The fastener may pass through or partially penetrate a support structure. In some embodiments, the fastener may be a screw, nail, bolt, peg, pin, rivet, clamp, buckle, snap, staple, clasp, tie, or any other type of mechanical fastener. In some embodiments, one or more components may be connected to one another by using an adhesive, eutectic bonding, thermosonic bonding, soldering, crazing, or welding, press or snap fitting, or using interlocking pieces.

### Methods

A method for illumination may include providing a lighting unit with one or more of the characteristics as previously described. For example, a method of illumination may include providing a lighting unit with a support structure, a circuit board, and one or more optical element. The method may include emitting light from one or more light emitting elements that may be supported by the circuit board. In some embodiments, the method may include hanging the light emitting elements over a side of the circuit board. A method for emitting light may further include allowing light emitted from one or more light emitting elements to reflect on a castellated surface of an optical element.

A method may be provided for assembling the lighting unit. For example, the method of assembly may include sandwiching a circuit board between a support structure and an optical element. The method may optionally include attaching the support structure, circuit board, and optical element using one or more fasteners. A further step may include tightening the fastener to tighten the contact between the support structure, circuit board, and optical element. In some embodiments, tightening the fastener may cause the shape of the circuit board to flex to better conform to the shape of the support structure, thereby forming a strong thermal contact with the support structure. The method may comprise forcing a curvature of a flexible circuit board such that at least a portion of the board is brought into better thermal contact with a heat dissipating structure without directly applying a force to said portion. For example, a portion of the flexible circuit board may have one or more light emitting elements disposed thereon, and forcing a curvature to the flexible circuit board may allow the portion of the flexible circuit board with the light emitting elements to form a strong thermal connection with the support without applying a force directly at the portion of the flexible circuit board with the light emitting elements. An intimate contact may be formed between a first region of the circuit board and the support without applying a direct force to the first region. The intimate contact may be formed between a first region of the circuit board and the support by applying a direct force to a second region. The method may also include affixing one or more secondary optical element to the support structure.

In some embodiments, contacting the circuit board with the optical element may include positioning one or more light emitting elements of the circuit board between one or more castellated protrusions of the optical element.

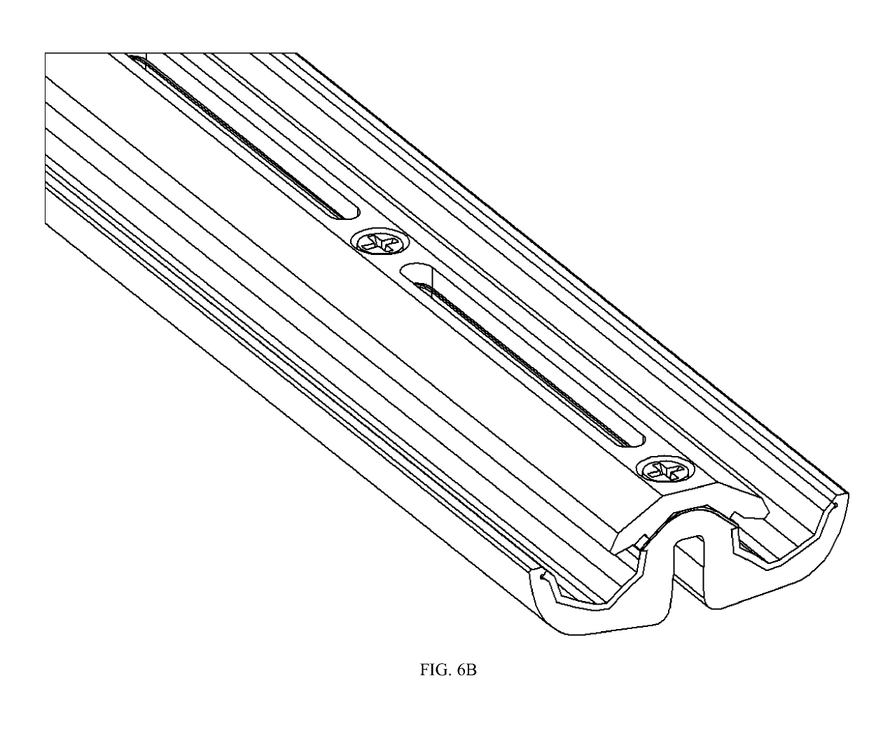

FIG. 6A shows an example of an assembled lighting unit provided in accordance with an alternate embodiment of the invention. A curved circuit board 600 may be provided between a base element 601 and a support structure 602. One or more portions of the base element may hang over and cover a portion of a side face of the circuit board. In some embodiments, a portion of a castellation 603 may hang over and cover a portion of a side face 604 of the circuit board. Secondary optical elements 605 may be provided in contact with the support structure.

Optionally, a space 606 may be provided between portions of the support structure. One or more thermal conduit 607 may be provided through a base element, circuit board, and support structure. The thermal conduit may be in fluid communication with the space provided between portions of the support structure. In some embodiments, a convection path may be formed, allowing air flow through the thermal conduit. One or more fastener 608 may be provided. In some embodiments, the fasteners may be located adjacent to or between the thermal conduits.

FIG. 6B shows another example of an assembled lighting unit provided in accordance with another embodiment of the invention. As previously discussed, the heat dissipating support and/or an optical element disposed thereon may be formed of a plurality of flat facets. Optionally the facets may extend lengthwise along the length of the support.

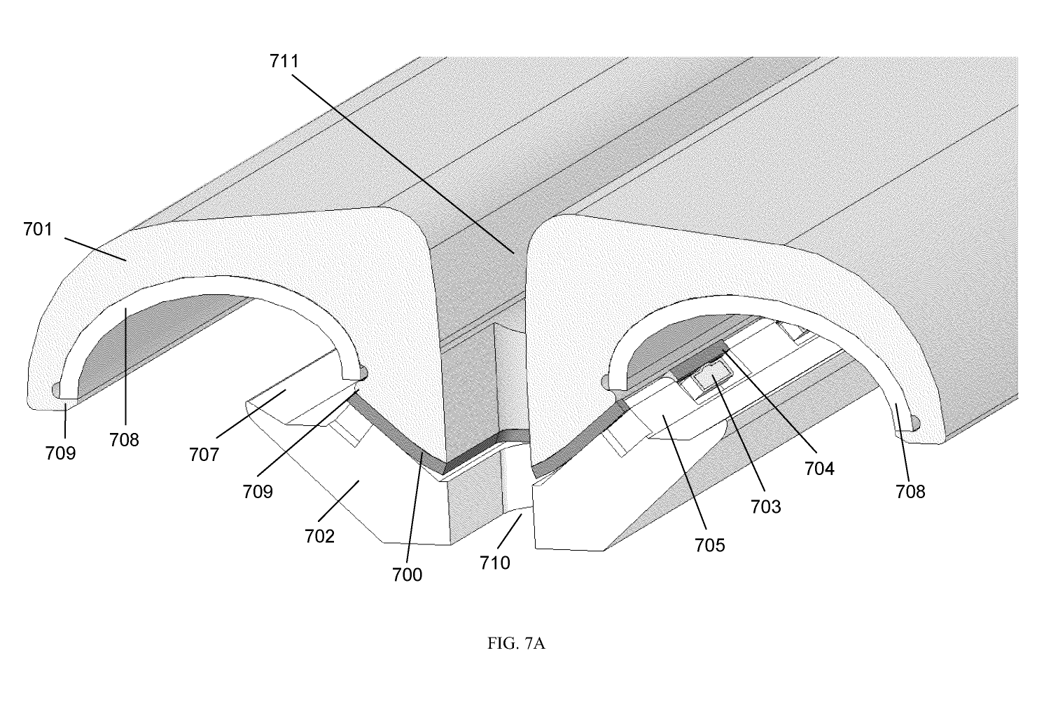

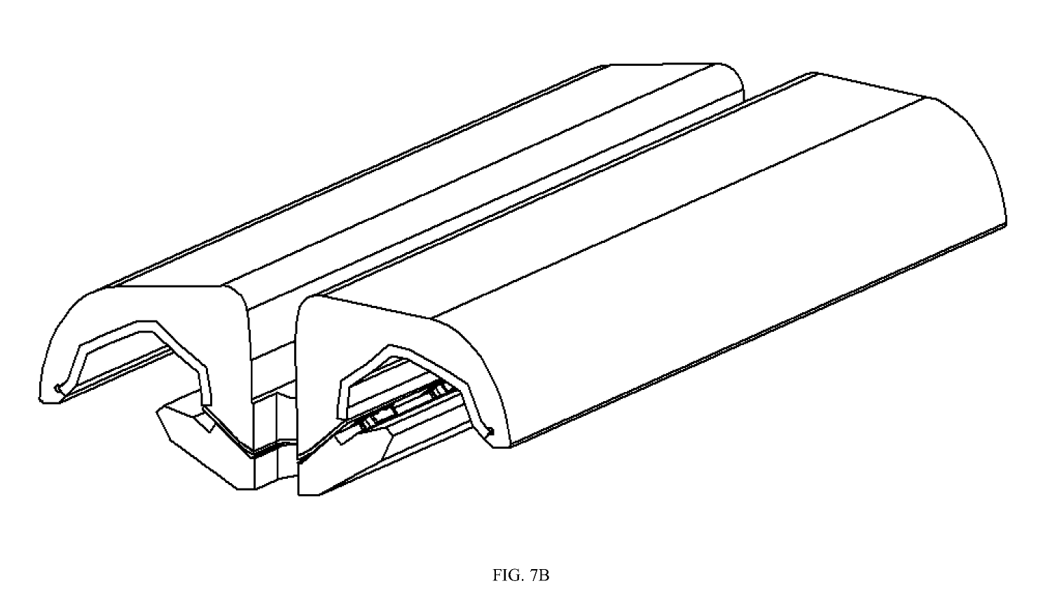

FIG. 7A shows a cross-section of an assembled lighting unit in accordance with an alternate embodiment of the invention. A circuit board 700 may be located between a support structure 701 and a base element 702. In some embodiments, the base element may be a reflector. The circuit board may support one or more light emitters 703 (e.g., LED package). The light emitters may hang over an edge of the circuit board. Alternatively, the circuit board may have one or more protruding portion 704 that may support the light emitters that extend beyond the recessed side of the circuit board.

The base element may include one or more castellations. A light emitting element may be provided between the protruding portions 705 of the castellations of the optical element. In some embodiments, a castellation may be provided between each light emitting element. Alternatively, a plurality of light emitting elements may be provided between protruding parts of the castellations. A portion of the protruding part of the castellation may cover a portion of a side face of the circuit board. In some embodiments, if the circuit board has protruding portions, the castellations may cover a recessed portion of the side face of the circuit board. The protruding portion of the castellation of the base element may or may not contact the support structure.

A ridge 707 may be provided on the base element, extending upwards. The ridge may block a light emitting element from a line of side outside the lighting unit.

One or more optical element 708 may be in contact with the support structure. The optical element may be fitted with a complementary shape into the support structure. The support structure may have one or more shelf or ridge 709 that may retain the optical element in position.

A thermal conduit 710 may be located traveling through the base element, circuit board, and the support structure. The thermal conduit may provide fluid communication between the bottom of the lighting unit with the space 711 within the support structure. In some embodiments, the thermal conduit may provide fluid communication between the bottom of the lighting unit and a top of the lighting unit.

FIG. 7B shows a cross-section of an assembled lighting unit in accordance with another embodiment of the invention. The heat dissipating support and/or an optical element disposed thereon may be formed of a plurality of flat facets. Optionally the facets may extend lengthwise along the length of the support.

### Cover

The lighting unit may optionally have a cover to protect the lighting unit from moisture, dirt and/or dust accumulation. The cover may be cleanable and may be made of plastic or glass, for example. In one embodiment, the cover comprises a substantially transparent cylindrical plastic sleeve that substantially encases the lighting unit or portions of the lighting unit. In some instances, a cover may be provided for each row of light emitting elements. For example, if two rows of light emitting elements are provided, two cover sections may be provided. In some embodiments, a cover, or a plurality of covers, may keep a thermal conduit open. In some implementations, a cylindrical shape of the cover may give the lighting unit the shape of a conventional fluorescent tube. The cover may be of other cross sectional designs and may encase any portion of the lighting unit or may not fully encase the lighting unit.

The cover may be an optical element. The cover can be optically engineered to improve light distribution or light extraction from the lighting unit. For example, the cover or a portion thereof, may have a textured surface, or may have a reflective layer, a lens, a microlens array, a low-index layer, a low index-grid, or a photonic crystal. In one embodiment, the internal upper portion of the cover is coated with a reflective metal to reflect light down and out of the lighting unit. The cover may be configured to convert the spectrum of light emitted by the lighting strip to another spectrum of light of a longer wavelength. For example, the cover can comprise a luminescent material such as a phosphor layer, or a quantum-dot-based film that can be configured for down-converting photons of higher energy to lower energy. The cover may also be a tinted or light filtering cover such that colored light may be provided by the lighting unit. The lighting unit may have multiple covers. For instance, each lighting strip within the lighting unit may have its own cover. The covers may be flat or curved pieces covering just a portion of the lighting unit and may provide additional optical control or protection from dust.

The cover may be configured to be removable and replaceable. For example, the cover may be configured to removably slide or snap onto the support structure of the lighting unit.

In some embodiments, the lighting unit is provided without a cover. A light emitting element may be an open-air light emitting element. In some embodiments, light emitted by the lighting unit does not substantially travel through a secondary optic.

### Control Module

The lighting unit is configured to be powered by a power supply. The power supply can be an external power supply. For example, if a lighting unit is used as a fluorescent tube replacement, the ballast in a conventional fluorescent lighting fixture can be bypassed or removed and replaced with the power supply, such that when the lighting unit is electrically coupled to the receptacles of the conventional fluorescent lighting fixture, the lighting unit is electrically connected to the external power supply. The power supply can be configured to convert wall alternating current to direct current to power the light emitting elements.

Alternatively, the power supply can be internal to the lighting unit. For example, the power supply can include a local energy storage system such as a battery, ultracapacitor, or induction coil.

The power supply can comprise a control module that can be used to drive the light emitting elements based on information gathered from a sensor, electronic interface, user input or other device, for example. The control module may individually address and control the lighting strips to adjust the color, pattern, brightness, light distribution or to compensate for aging, for example. The control module may be configured to modulate illumination from the light emitting elements. For instance, the control module may drive the lighting unit such that the light emitting elements flash or are activated in a pattern. Furthermore, the control module can drive the light emitting elements using pulse width modulation or amplitude modulation. The control module can be used to dim the light output of the lighting unit.

It should be understood from the foregoing that, while particular implementations have been illustrated and described, various modifications can be made thereto and are contemplated herein. It is also not intended that the invention be limited by the specific examples provided within the specification. While the invention has been described with reference to the aforementioned specification, the descriptions and illustrations of the preferable embodiments herein are not meant to be construed in a limiting sense. Furthermore, it shall be understood that all aspects of the invention are not limited to the specific depictions, configurations or relative proportions set forth herein which depend upon a variety of conditions and variables. Various modifications in form and detail of the embodiments of the invention will be apparent to a person skilled in the art. It is therefore contemplated that the invention shall also cover any such modifications, variations and equivalents.

What is claimed is:

1. A lighting unit comprising:
a support structure;
a circuit board extending substantially along the length of the support structure;
a plurality of light emitting elements disposed along a length of the circuit board; and
an at least partially reflective reflector extending substantially along the length of said support with a plurality of shaped features covering at least a portion of the circuit board edge between the light emitting elements.

2. The lighting unit of claim 1 wherein the plurality of shaped features are protruding portions of castellations formed on the reflector.

3. The lighting unit of claim 2, wherein the castellations also include recessed portions along which one or more light emitting element is disposed.

4. The lighting unit of claim 3, wherein the circuit board includes a protruding portion which fits along a recessed portion of the castellations between protruding portions of the castellations.

5. The lighting unit of claim 2, wherein the protruding portions of the castellations include a lip that lies over at least a portion of a side of the circuit board.

6. The lighting unit of claim 2, wherein the castellations are located on a surface of the optical element facing one or more light emitting elements.

7. The lighting unit of claim 1 wherein the reflector is at least partially formed from a translucent material.

8. The lighting unit of claim 1, wherein the light emitting elements are light emitting diodes.

9. The lighting unit of claim 1, wherein a luminescent material is disposed on said reflector, wherein said luminescent material is configured to be excited by light emitted from at least one of said light emitting elements.

10. A lighting strip comprising:
a support structure;
a circuit board extending substantially along the length of the support structure; and
a plurality of light emitting elements disposed along a length of the circuit board and extending over an edge said circuit board.

11. The lighting strip of claim 10, wherein the circuit board comprises a first edge and a second edge, and wherein a plurality of light emitting elements extend over the first edge, and a plurality of light emitting elements extend over the second edge.

12. The lighting strip of claim 11, wherein a plurality of light emitting elements are positioned on the first edge and a plurality of light emitting elements are positioned on a second edge along the substantially the same length of the circuit board.

13. The lighting strip of claim 10, wherein the light emitting elements are spaced apart so the distance between the light emitting elements is greater than the length of the light emitting elements.

14. The lighting strip of claim 10, wherein an individual light emitting element of said plurality emits light in an upward direction and a downward direction simultaneously.

15. The lighting strip of claim 10, wherein the circuit board has a passageway therethrough, configured to permit the flow of a fluid through the lighting strip.

16. A lighting unit comprising:
a heat-dissipating support structure with a curved surface;
a flexible circuit board extending substantially along the length of the support structure that is curved to provide contact the curved surface of the support structure; and
a plurality of light emitting elements disposed along a length of the circuit board.

17. The lighting unit of claim 16, wherein the flexible circuit board is sandwiched between the support structure and an optical element.

18. The lighting unit of claim 17, wherein the optical element comprises a concave surface that is configured to contact a convex curved surface of the flexible circuit board.

19. The lighting unit of claim 17, wherein the optical element is formed of a reflective material.

20. The lighting unit of claim 16, wherein the heat-dissipating support structure further comprises one or more additional optical element disposed thereon.

21. A method of assembling a lighting unit, comprising:
providing a curved heat-dissipating structure;
providing a flexible circuit board with a plurality of light emitting elements; and
inducing a curvature in the flexible circuit board such that the portion of the circuit board with the light emitting elements is brought into intimate contact with the curved heat-dissipating structure without directly applying force to said portion of the circuit board.

22. The method of claim 21, wherein the force is applied by an optical element, wherein the flexible circuit board is sandwiched between the heat-dissipating structure and the optical element.

23. The method of claim 22, wherein the optical element is at least partially formed of a translucent material.
